(19) United States
(12) Patent Application Publication
(10) Pub. No.: US 2026/0150194 A1
(43) Pub. Date: May 28, 2026

(54) EXTENDED PAD AREA TO PREVENT PRINTED CIRCUIT BOARD DAMAGE

(71) Applicant: Kollmorgen Corporation, Radford, VA (US)

(72) Inventors: Jeffery Todd BREWSTER, Dublin, VA (US); William Edward ANDERSON, IV, Blacksburg, VA (US); Stephen John FUNK, Riner, VA (US); Peter BENOIT, Blacksburg, VA (US); Ron KLUEVER, Wake Forest, NC (US); Jacob Roy ABER, Christiansburg, VA (US)

(73) Assignee: Kollmorgen Corporation, Radford, VA (US)

(21) Appl. No.: 19/429,568

(22) Filed: Dec. 22, 2025

Related U.S. Application Data
(63) Continuation-in-part of application No. 18/240,688, filed on Aug. 31, 2023, now Pat. No. 12,520,434.
(60) Provisional application No. 63/402,699, filed on Aug. 31, 2022.

(51) Int. Cl. H05K 1/11; H05K 1/02; H05K 3/20

(52) U.S. Cl. CPC H05K 1/111; H05K 1/0271; H05K 3/20; H05K 2201/0939; H05K 2201/099

(57) ABSTRACT

A printed circuit board includes an electrically insulative layer and a conductive pad disposed over the electrically insulative layer. The conductive pad defines a contact area for attachment of a conductor and is partially covered by a solder mask that defines an exposed region of the conductive pad. The conductive pad extends underneath the solder mask along a periphery of the exposed region to form an extended pad area. The extended pad area protects the electrically insulative layer from thermal, mechanical, electrical, and vibrational damage during attachment of the conductor. The extended pad area further accommodates positional variation of non-rigid conductors resulting from inherent spring force introduced during prior manufacturing processes. Pad extension dimensions may be determined as a function of conductor length, pad geometry, and a spring displacement angle of the conductor. The configuration is applicable across multiple joining processes and improves manufacturability of printed circuit board assemblies.

### CROSS REFERENCE TO RELATED APPLICATIONS

This application is a Continuation in Part of U.S. application Ser. No. 18/240,688 filed Aug. 31, 2023 entitled EXTENDED PAD AREA TO PREVENT PRINTED CIRCUIT BOARD DAMAGE, which claims the benefit of and priority to U.S. Provisional Application No. 63/402,699 filed Aug. 31, 2022 entitled CONNECTION BETWEEN A MOTOR AND A PRINTED CIRCUIT BOARD, the contents of which are incorporated herein by reference in its entirety for any purpose whatsoever.

### FIELD OF THE DISCLOSURE

The subject of this disclosure relates to printed circuit boards, and more particularly to conductive pads and solder pads configured to prevent damage to a printed circuit board and to accommodate placement tolerance of conductors during attachment of conductors to the printed circuit board by one or more joining processes, including soldering and other thermal, mechanical, electrical, and/or vibrational joining techniques.

### BACKGROUND

A printed circuit board is a multi-layer structured device that makes electrical connections between electronic components. The layers of a printed circuit board may vary, but generally consist of a base material and copper foil laminate that are pressed together and cured with heat to form the core of the printed circuit board. Multiple layers of conductive material are arranged alternately with electrically insulative layers. The metallic layers of the printed circuit board can be etched to form electrical traces that construct an electrical circuit. Multiple conductive layers can also be connected to each other by vias. The top metal layer in a printed circuit board is coated with a solder mask layer. The solder mask layer defines the perimeter of the solder pad i.e., the area of the metal that is exposed and available to make electric connections.

Conductors, such as wires and leads, are commonly attached to printed circuit boards using joining processes including soldering (manual, robotic, and/or laser soldering), thermal compression bonding, resistance welding, ultrasonic welding, and other techniques that apply heat, pressure, current, and/or vibration to form a conductive joint. The size and shape of the conductive pad used for the joint can affect the joining process, heat distribution, current density distribution, mechanical stress distribution, and the overall mechanical and electrical performance of the connection.

A known challenge in printed circuit board manufacturing is preventing damage to the printed circuit board material adjacent to the conductive pad during conductor attachment. For soldering processes, thermal energy may be applied outside the intended pad area due to tool misalignment, part-to-part variability, or reflected energy, resulting in scorching, delamination, or loss of dielectric integrity in the electrically insulative layers. For resistance welding and thermal compression bonding, significant mechanical stresses may be imparted to the pad region and underlying base material. For ultrasonic welding, vibrational energy may create localized stress concentrations and heat generation. In each case, excessive localized thermal and/or mechanical loading can damage the printed circuit board composite structure, potentially destroying insulation between conductive layers and causing device failure.

A further and distinct challenge arises in printed circuit board applications that utilize non-rigid conductors, such as armature conductor wires, particularly in electric motor assemblies. Armature conductor wires may exhibit inherent spring force characteristics resulting from upstream manufacturing processes such as winding, forming, cutting, and handling. These processes introduce residual stresses that cause the conductor to spring toward a previous condition, which creates consistent placement variation when positioning the conductor for attachment to a conductive pad. This behavior contrasts with designs using surface-mounted components, which typically have rigid conductors that are more predictable and can be placed with significantly tighter positional tolerances. The placement variability associated with armature conductors, combined with applied thermal and/or mechanical energy during joining, increases the likelihood of misplacement, localized pad loading, and damage to the printed circuit board base material.

Protecting a printed circuit board from damage during conductor attachment is a known challenge within the electronics industry, and several disclosures exist to address aspects of this problem, including protection from burning during laser soldering and related processes. In one such disclosure (U.S. Pat. No. 10,772,214 B2), a pin is inserted in a through-hole of a solder contact and welded in place. A white coating on the solder contact reflects the laser beam and the angle of the laser beam is adjusted so that the rate of energy absorption is decreased and damage to an insulated part is restrained. An irradiation angle of the laser beam for welding with respect to the circuit board is adjusted so that the laser light reflected off the terminal pin strikes the white layer on the solder contact. Reflecting off the white coating on the board and adjusting laser angle prevents excessive heating of the insulating element.

In U.S. Pat. No. 7,134,592 B2, temperature-sensitive electronic components that are connected to a board by soldering during the installation process are protected from heat during the soldering process in order to prevent permanent damage to the components. The solder connections of the component are thermally coupled to a protection apparatus during the soldering process, so that some heat introduced into the solder connections during soldering is passed to the protection apparatus. The protection apparatus also has a protection sleeve, which surrounds the component in places. The protection sleeve is composed of a thermally insulated material and is provided with a coating having high thermal reflection capability in places on its outer wall which faces away from the component.

In Japanese Patent No. 2014107424A, the shape of the leading part of a terminal of an electronic component is configured to prevent burning of a circuit board surface resulting from fusion of solder by a laser beam. In an electronic circuit device including a circuit board on which electronic components are mounted, a terminal inserted in a through-hole is joined to a solder contact on the circuit board via solder fused by a laser beam emitted from a laser light source. The shape of the leading end part of the terminal and an exposed margin of the terminal are set so that direct light from the laser light source and light reflected by the leading end part of the terminal do not overlap on the surface of the circuit board other than on the solder contact.

In Japanese Patent No. 2006173282A, an electronic part soldering method and device are provided to protect a substrate against burning. The soldering method includes soldering a lead to solder contacts of a printed board by irradiation with a laser beam. A light shading member equipped with a cylinder is arranged on the surface of a base so as to include an insertion tip of the lead and the land in an opening region to prevent the surface of the base around the land from being irradiated directly and/or indirectly with the laser beam, and the lead is irradiated with the laser beam through the cylinder.

While such disclosures may address certain aspects of thermal protection in particular joining contexts, they do not address the combined problem of (i) protecting a printed circuit board base material from damage caused by thermal, mechanical, electrical, and/or vibrational joining energy and (ii) accommodating placement variation of non-rigid conductors, such as armature conductor wires exhibiting spring force, across multiple joining processes. There remains a need for improved conductive pad designs that provide robust protection to the printed circuit board while permitting increased positional tolerance for conductors during attachment, independent of the specific joining method employed.

### SUMMARY

Printed circuit boards are commonly used to attach conductors, such as wires or leads, to conductive pads disposed over electrically insulative base materials. Attachment processes may apply thermal, mechanical, electrical, and/or vibrational energy to form an electrical connection. In applications employing non-rigid conductors, including armature conductor wires, residual stresses introduced during prior manufacturing operations may cause the conductor to exhibit spring force, resulting in positional variation when the conductor is placed for attachment. This placement variability, combined with applied joining energy, increases the likelihood of localized stress and damage to the electrically insulative base material.

The disclosure provides a printed circuit board including an electrically insulative layer, a conductive pad disposed at least partially over the electrically insulative layer, and a solder mask disposed over the conductive pad. The conductive pad defines a contact area for attachment of a conductor, and the solder mask defines an exposed region of the conductive pad. The conductive pad extends underneath the solder mask along a periphery of the exposed region to form an extended pad area. The extended pad area protects the electrically insulative layer during attachment of the conductor while preserving electrical connectivity at the exposed contact area.

The extended pad area further accommodates positional variation of the conductor resulting from spring force inherent in the conductor. The length of extension of the conductive pad may be dependent on geometric characteristics of the contact area, including height and width, and on a spring displacement angle that accounts for angular displacement of the conductor caused by residual stress. The spring displacement angle may vary based on conductor diameter and upstream manufacturing processes and, in some implementations, ranges from approximately 5 degrees to approximately 25 degrees.

The length of extension of the conductive pad may be determined according to a trigonometric relationship that accounts for conductor length, pad width, contact area geometry, and the spring displacement angle of the conductor. In particular, the extension length may be calculated as a function of a sine of the spring displacement angle to ensure that sufficient conductive surface area is provided to receive the conductor across an expected range of positional variation, while maintaining protection of the electrically insulative layer.

The conductive pad may extend underneath the solder mask by a distance selected to balance protection and process performance. In some implementations, the extension length ranges between approximately 0.25 millimeters and approximately 2.5 millimeters. The conductive pad may extend substantially around a periphery of the contact area, less a channel configured to receive the conductor, thereby providing protection in multiple directions while permitting conductor placement.

The disclosed conductive pad configuration is applicable across multiple joining processes, including manual soldering, robotic soldering, thermal compression bonding, resistance welding, ultrasonic welding, and other conductor attachment techniques. Depending on the joining process employed, the extended pad area provides thermal buffering, mechanical stress distribution, current density management, and/or vibrational energy dampening, while simultaneously accommodating conductor placement variation caused by spring force.

The disclosure further provides a method of creating a connection on a printed circuit board. The method includes disposing a conductive pad adjacent an electrically insulative base layer, coating the conductive pad with a solder mask such that the conductive pad extends underneath the solder mask to form a peripheral extension, and attaching a conductor to an exposed contact area of the conductive pad using a joining process. The peripheral extension accommodates positional variation of the conductor and protects the electrically insulative base layer from damage incurred during the joining process.

Through the combination of extended pad geometry and spring-force-aware placement tolerance, the disclosed technology provides a generalized conductive pad architecture that improves manufacturability, increases allowable placement tolerance for non-rigid conductors, and enhances reliability of printed circuit board assemblies across a wide range of conductor attachment processes.

### BRIEF DESCRIPTION OF THE DRAWINGS

Various aspects of the present disclosure are discussed herein with reference to the accompanying Figures. It will be appreciated that for simplicity and clarity of illustration, elements shown in the drawings have not necessarily been drawn accurately or to scale. For example, the dimensions of some of the elements can be exaggerated relative to other elements for clarity or several physical components can be included in one functional block or element. Further, where considered appropriate, reference numerals can be repeated among the drawings to indicate corresponding or analogous elements. For purposes of clarity, however, not every component can be labeled in every drawing. The Figures are provided for the purposes of illustration and explanation and are not intended as a definition of the limits of the disclosure.

FIG. 1 shows a schematic diagram of a cross-section of a conventional printed circuit board, exhibiting the variable layers therein.

FIGS. 2A-2B show overhead, perspective views of example damage specimens to a printed circuit board incurred during laser soldering. Excessive heat may cause the printed circuit board to delaminate or destroy the necessary insulative properties of the composite. If the insulation between two metal layers breaks down, the electrical circuit is destroyed, and device failure is likely to result.

FIG. 3 shows an overhead, plan view of a solder mask defining a solder contact area for soldering wire.

FIGS. 4A-4B show two overhead, plan views for solder pads, comparing a design known in the art in FIG. 4A to the design for the solder pad of the present disclosure in FIG. 4B. In FIG. 4B, the area of the solder pad extends beyond the area exposed by the solder mask to protect the underlying and adjacent base material. If heat is applied outside the solder area, the extended pad absorbs the heat and the printed circuit board is not damaged.

FIGS. 5A-5B show overhead, plan views of a 2.5 mm wide solder contact. By increasing the size of the solder pad beneath the solder mask to have a protective border region that is 0.50 mm wide, as shown in FIG. 5B, the underlying and adjacent insulative base material is protected from thermal damage due to laser soldering.

FIGS. 6A-6B show overhead, plan views of a 3.5 mm wide solder contact. By increasing the size of the solder pad beneath the solder mask to have a protective border region that is 0.75 mm wide, as shown in FIG. 6B, the underlying and adjacent insulative base material is protected from thermal damage due to laser soldering.

FIGS. 7A-7B show overhead, plan views of electrically isolated solder contacts on the top layer of a printed circuit board, FIG. 7A exhibiting a design known in the art, while FIG. 7B exhibits an increased solder pad size beneath the solder mask according to the present disclosure.

FIGS. 8-9 show overhead, plan views of solder pads connected to traces etched into the top metal layer of a printed circuit board accordingly to the subject disclosure.

FIG. 10 shows an overhead, plan view of a solder contact area and illustrates a methodology in determining the size of the solder pad extending beneath a solder mask.

FIG. 11 shows an overhead, plan view of a solder contact area illustrating an extended conductive pad configured to accommodate positional variation of a conductor wire due to spring force characteristics and to protect a printed circuit board during attachment of the conductor wire across multiple joining processes.

### DETAILED DESCRIPTION

The subject technology overcomes many of the prior art problems associated with printed circuit boards and attachment of conductors to conductive pads. The advantages, and other features of the technology disclosed herein, will become more readily apparent to those having ordinary skill in the art from the following detailed description of certain exemplary embodiments taken in combination with the drawings and wherein like reference numerals identify similar structural elements. It should be noted that directional indications such as vertical, horizontal, upward, downward, right, left and the like, are used with respect to the figures and not meant in a limiting manner.

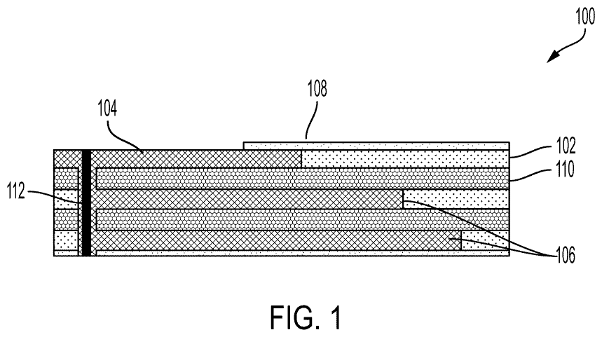

A cross-sectional schematic of a printed circuit board 100 is shown in FIG. 1. A printed circuit board 100 is a multi-layer structured device that makes electrical connections between electronic components. The layers of the printed circuit board 100 may vary, but generally consist of a base material 102 and copper foil laminate 104.

The base material 102 consists of a glass substrate upon which a flame-retardant (FR) epoxy resin, such as a resin meeting the requirements of UL94V-0, is deposited and partially cured. The base material 102 is electrically insulative and provides electrical isolation for the successive metal layers that is necessary for the device to function. FR4 is a typical material used to construct the layer 102 of the printed circuit board 100 due to the strength-to-weight ratio, waterproof properties, and manufacturability. This material has a temperature index of 110° C. to 150° C., the maximum service temperature at which the critical properties of a material will remain within acceptable limits over a long period of time. In one embodiment, FR4 is made from a flame retardant epoxy resin and glass fabric composite. Furthermore, FR4 has notable adhesive properties to copper foil and has minimal water absorption.

The printed circuit board 100 also consists of alternating layers of copper foil 106 and insulation 110. During manufacturing, heat is applied to bond the layers 102, 106, 110 together. The copper foil layers 106 are electrochemically etched to define copper traces that conduct electricity and form the electrical circuit of the device, electrically connected together by a via 112.

The top copper surface 104 of the laminate is coated with a patterned solder mask 108 to define areas of copper that are exposed to make electrical connections to the board 100. Solder is used to make the electrical connections between the top copper surface 104, wires (not distinctly shown), and component electrical leads (not distinctly shown).

The top metal layer 104 of the printed circuit board 100 has a solder contact area that is limited in size by the solder mask 108. The area of the solder contact area needs to be large enough so that it contains the exposed length of wire and resulting solder joint. Sufficient heat is required to fully melt the solder without damaging the printed circuit board 102 laminations. If the solder pad is large, more time and heat are required to fully heat the assembly to the desired temperature.

Lasers can be used to impart thermal energy to precisely localized areas in the soldering process. Laser soldering is described herein as one example of a joining process and is not intended to be limiting, as other joining processes applying thermal, mechanical, electrical, or vibrational energy may similarly benefit from the disclosed conductive pad architecture. If laser heat is applied to areas adjacent to the solder pad, such as by incident laser light reflecting off of the solder onto the printed circuit board 100, the base material 102 or the insulative layers 110 may be damaged. Excessive heat may cause the printed circuit board 100 to delaminate or destroy the necessary insulative properties of the composite.

For context, solder is a fusible metal alloy with a low melting temperature and low surface tension that is used to bond electrically conductive surfaces in the construction of electrical devices. Solder generally has a range of melting temperatures from 90° C. to 450° C. The composition of the solder alloy determines the melting temperature. Alloys with higher or lower melting temperature can be selected and mixed to achieve optimal properties for manufacturability of electrical connections. A two-phase mixture of a low and high melting temperature alloys may be chosen and prepared with flux that reduces the surface tension of the molten alloy. This mixture may be prepared into a soldering paste or wire depending on the application.

In order to make the electrical connection, two components to be connected are brought into close proximity with solder and the assembly is heated to melt the solder to flow and coat the surfaces of both components. The molten solder is allowed to cool and solidify. In this way, a connection can be made with electrical conductivity. The mechanical and electrical quality of the connection depends upon achieving an appropriate temperature for the assembly. Temperatures in excess of 200° C. are often required to melt solder paste and form high quality connections.

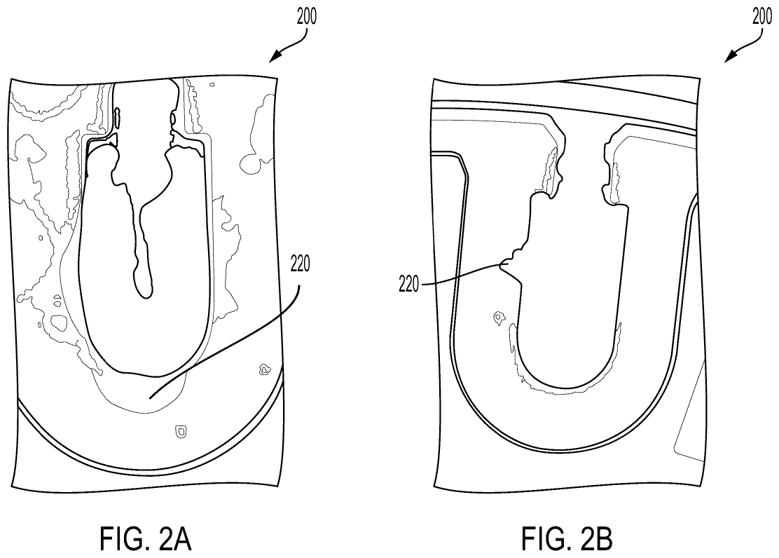

FIGS. 2A-2B show examples of damage 220 to a printed circuit board 200 incurred during laser soldering. As mentioned supra, once the insulation between two metal layers of the printed circuit board 200 breaks down, the electrical circuit is destroyed, and device failure is likely to result.

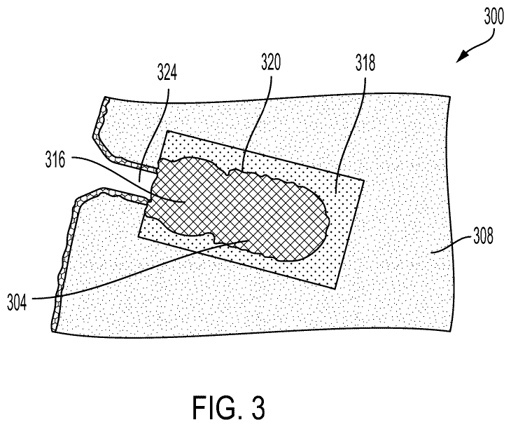

Referring now to FIG. 3, in an aspect of the present disclosure, the solder mask 308 defines a solder contact area 304. Yet, the solder pad 316 extends beyond the contact area 304 exposed by the solder mask 308 to protect the underlying and adjacent base material and adjacent material forming the printed circuit board 300. The extension of the solder pad 316 is referred to herein as a protective border region 318. Preferably, the protective border region 318 is fully disposed around a periphery 319 of the solder contact area 304, providing heat protection in all directions relative to the solder contact area 304, less a channel 324 for receiving a conductive wire for connection to the board 300.

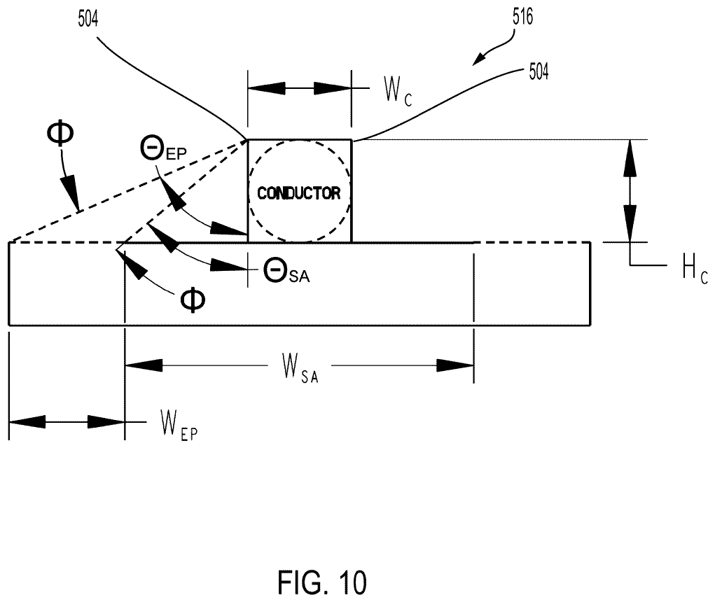

In this embodiment, if heat is applied outside the solder area 304, and onto an edge 320 of the solder mask 308, the pad 316 absorbs the heat by virtue of the pad 316 extending underneath the edge 320 of the solder mask 308. Consequently, the layers of the printed circuit board 300 are heat protected. It's worth noting that to facilitate quicker soldering, the amount of copper around the area of the pad 304 defined by the solder mask 308 needs to be minimized, but large enough to provide the protection to the printed circuit board 300 insulative layers. The optimization of such is discussed with reference to FIG. 10 below.

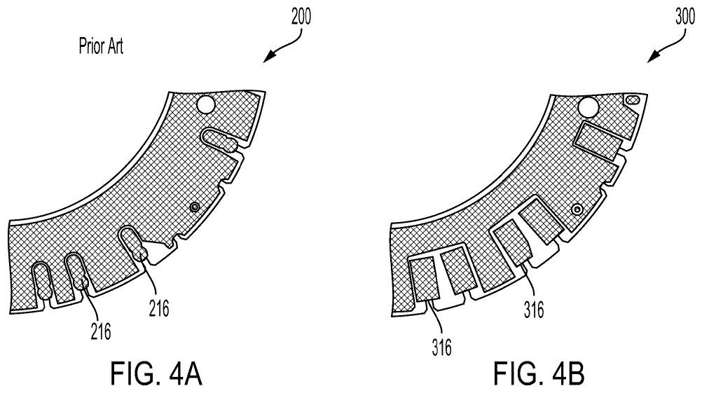

Further to the description of FIG. 3, FIGS. 4A and 4B contrast schematic illustrations of solder pads 216 embedded on a printed circuit board known in the art 200 and solder pads 316 of an improved printed circuit board 300 design. As presented, the pad 316 of the improved printed circuit board 300 extends underneath the edge of the solder mask 308, thus protecting layers of the improved printed circuit board 300 from incident heat during the solder process.

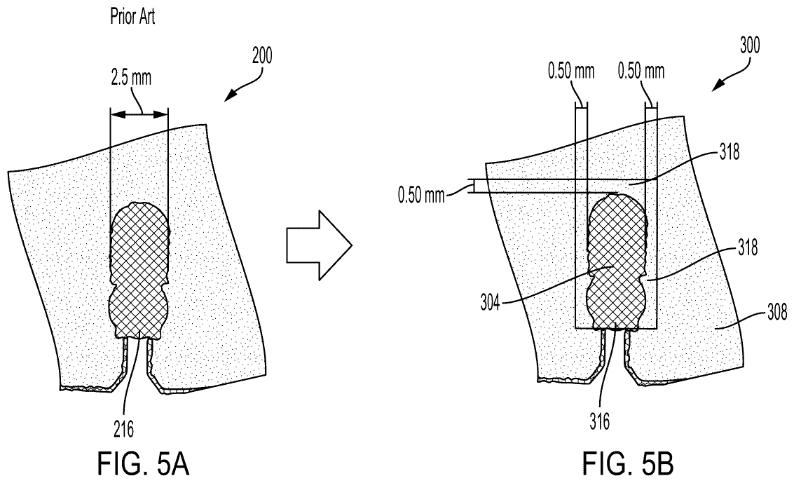

FIG. 5A and FIG. 5B show further example comparisons of the printed circuit board known in the art 200 and the improved printed circuit board 300 designs. The solder pad 216 in FIG. 5A is 2.5 mm wide. By contrast, as shown in FIG. 5B, solder pad 316 has an increased width of 3.5 mm, providing a 0.50 mm lateral extension of solder pad 316 beneath the solder mask 308. Further, the height of the solder pad 316 is increased by 0.50 mm. Accordingly, the protective border region 318 of FIG. 5B is disposed around the periphery of the solder contact area 304 by 0.50 mm in all directions, thus protecting the underlying and adjacent insulative base material (not distinctly shown) from thermal damage due to laser soldering completed within the contact area 304.

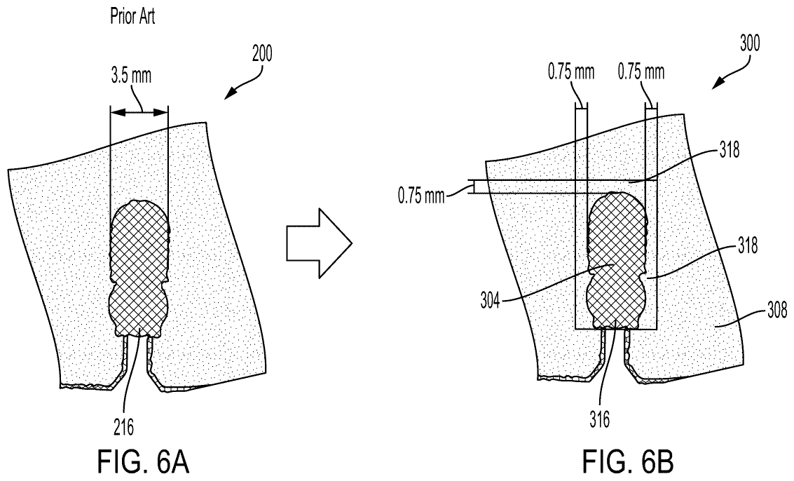

FIG. 6A and FIG. 6B show further example comparisons of the printed circuit board known in the art 200 and improved printed circuit board 300 designs. Here, the solder pad 216 in FIG. 6A is 3.5 mm wide. By contrast, as shown in FIG. 6B, solder pad 316 has an increased width of 5.0 mm, providing a 0.75 mm lateral extension of solder pad 316 beneath the solder mask 308. Further, the height of the solder pad 316 is increased by 0.75 mm. Accordingly, the protective border region 318 of FIG. 6B is disposed around the periphery of the solder contact area 304 by 0.75 mm in all directions, thus protecting the underlying and adjacent insulative base material (not distinctly shown) from thermal damage due to laser soldering completed within the contact area 304.

In FIGS. 5B and 6B, the width of the protective border region 318 is approximately 20% of the width of the solder contact 304. This profile factor is sufficient to provide protection to the underlying and adjacent base material, while not so large so as to add excessive thermal mass to the assembly that would require more heating to form the high-quality electrical connection.

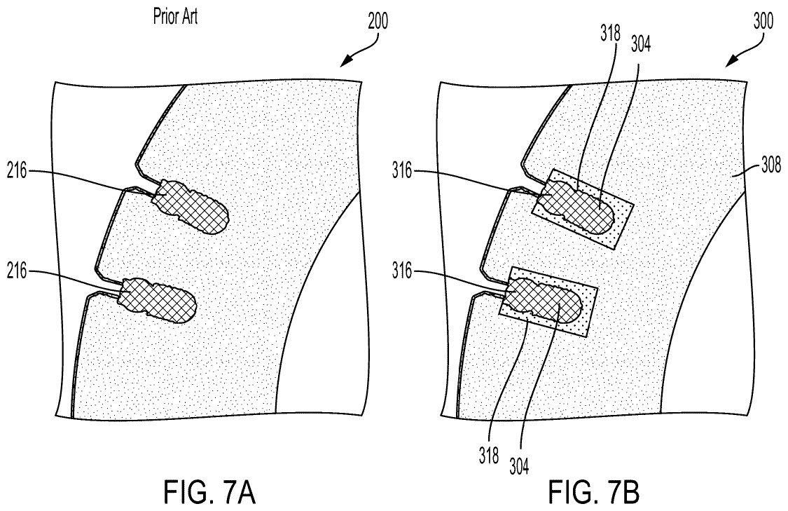

Referring now to FIGS. 7A-7B, the printed circuit board known in the art 200 and improved printed circuit board 300 are further juxtaposed in an embodiment with electrically isolated solder contacts. In this regard, solder contacts 304 on the top layer of the printed circuit board 300 may be electrically isolated on a first metallic layer of the composite structure. These isolated solder pads 316 may be connected to underlying metal layers by vias as shown in FIG. 1. Nonetheless, the principles discussed herein still apply, in that the solder pad 316 of the present disclosure provides a protective border region 318 disposed around the periphery of the solder contact area 304 for thermal protection.

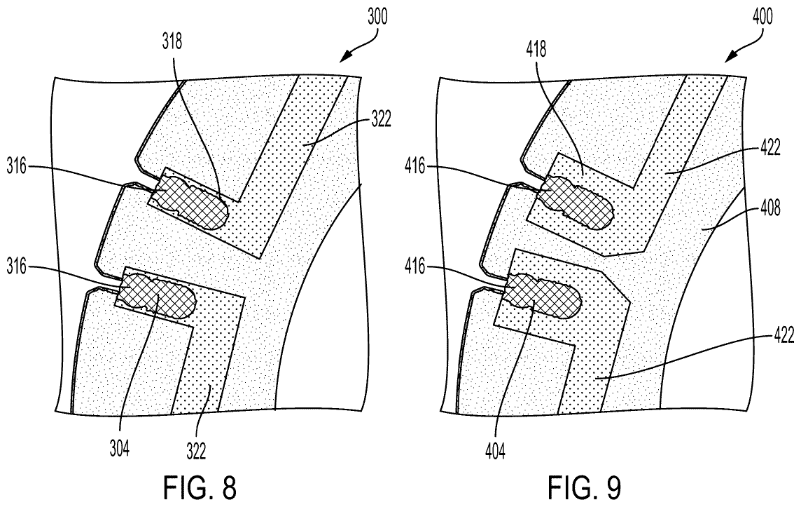

FIGS. 8-9 show different embodiments of improved printed circuit boards 300, 400 having solder pads 316, 416 with protective border regions 318, 418. The solder contacts 304, 404 on the top layer of the printed circuit boards 300, 400 are connected to traces 322, 422 etched into the top metal layer of the printed circuit boards 300, 400. Still, the solder pads 316, 416 provide a protective border region 318, 418 disposed around the periphery of each solder contact area 304, 404 for thermal protection. The illustrations of FIGS. 8-9 further show that in an embodiment of the disclosure, a width of the solder pad 316, 416 may be increased by a protective border 318, 418 width that is on the order of the width of the exposed solder contact area 304, 404 independent of and without modification to the trace 322, 422.

Referring now to FIG. 10, a solder contact area 504 of a solder pad 516 is shown in plan view. Although illustrated in the context of laser soldering, the methodology of FIG. 10 is representative of energy misplacement considerations applicable to other joining processes. The width W_{SA} of the solder pad 516 is normally determined by the size of the conductor 516 that will potentially be soldered onto the given solder pad 516. However, an improved and safer connection is made by selecting the size of the solder pad 516 based on how the manufacturing process of laser soldering can allow heat to be focused outside the solder contact area 504.

For example, the height and width of the solder contact area 504, H_{C} and W_{C}, can be referenced to determine a minimum angle of reflection, θ_{SA}, that would account for a laser in a laser soldering process reflecting outside of the solder contact area 504. A supplemental angle, φ, accounting for part tolerances, conductor placement and variations of the laser soldering process, can thereafter be added to θ_{SA}, to calculate a maximum angle of reflection, θ_{EP}. In this example, the angle, φ, normally ranges between 5 degrees and 30 degrees. The maximum angle of reflection, θ_{EP}, can thereafter be used to calculate the size of the solder pad extension, W_{EP} based on the equation mentioned below.

$${W}_{E P} = {H}_{C} * tan \{ {θ}_{S A} + ϕ \} - \frac{{W}_{S A}}{2} + \frac{{W}_{C}}{2}$$

$$5 < ϕ < 30 degrees$$

Further, the conductor shape for aforementioned calculation could be square, rectangular, or a round shape approximated as square. Other commercially available conductor shapes, of which may contain rounded edges, can be used in the aforementioned calculation given their approximate width and height.

As an aside, several factors contribute to achieving good quality solder connections while preserving the layered electric structure of a printed circuit board, including the thermal properties of the solder process and assembly technique. These factors may include the width of the copper exposed by the solder mask material (not distinctly shown), or the diameter and morphology of the wire to be soldered. As an example, thicker wire requires more heat and solder to make a strong connection. Similarly, wire comprised of a single conductor or multiple strands influences the process. Furthermore, the amount of solder or solder paste required will depend on the size of the solder contact area and the characteristics of the wire. All of these factors will determine the amount of heat required to melt the solder and form a strong electrical connection.

While the embodiments described above are primarily illustrated in the context of laser soldering, the underlying technical principles addressed by the extended pad area are not limited to laser-based joining processes. In printed circuit board applications—particularly those involving armature conductor wires—the conductor wires commonly exhibit inherent spring force characteristics resulting from upstream manufacturing operations such as winding, forming, and handling. These spring forces introduce predictable yet unavoidable placement variability when positioning the conductor relative to a solder pad or other conductive contact area. This behavior stands in contrast to surface-mounted component designs, which typically employ rigid conductors with significantly tighter dimensional tolerances.

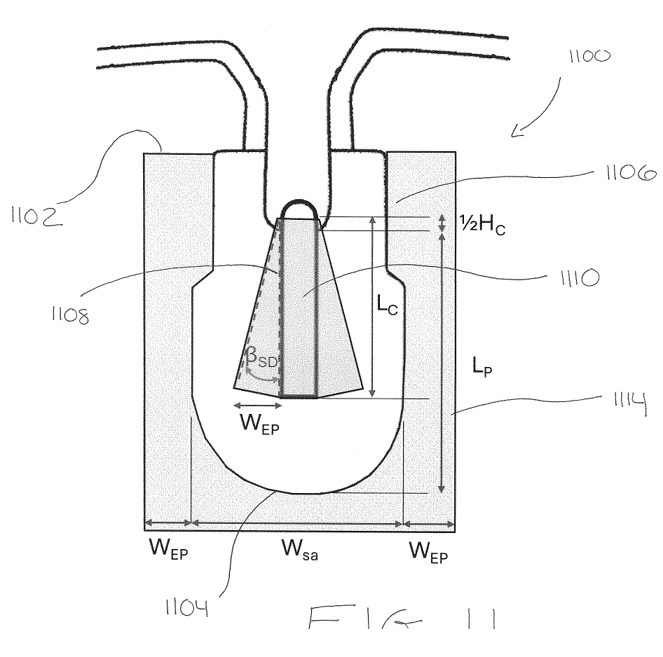

The embodiments described with reference to FIG. 11 therefore address a more general class of conductor-to-board attachment challenges that arise across multiple joining processes. Regardless of whether the attachment is performed using manual soldering, robotic soldering, thermal compression bonding, resistance welding, ultrasonic welding, or similar techniques, the combination of conductor spring force and applied thermal and/or mechanical energy can result in localized stress and potential damage to the printed circuit board base material. The extended pad area described herein provides a generalized solution that accommodates conductor placement variability while protecting the printed circuit board from thermal, mechanical, and vibrational damage during conductor attachment, independent of the specific joining method employed.

Advantageously, by decoupling the protective and tolerance-accommodation functions of the extended pad area from any single joining process, the disclosed technology enables increased robustness, manufacturability, and process flexibility in printed circuit board assemblies. The extended pad area permits relaxed placement tolerances for conductor wires without sacrificing electrical reliability, reduces sensitivity to tool alignment and process variation, and mitigates damage mechanisms associated with concentrated heat, pressure, current density, or vibrational energy. As a result, the technology supports broader process windows, facilitates automation and mixed-process manufacturing environments, and improves yield and long-term reliability for assemblies that employ non-rigid conductors, particularly in applications where conductor geometry, size, or spring force would otherwise limit feasible joining methods.

FIG. 11 shows an overhead, plan view of a solder contact area 1108 and illustrates an embodiment of an extended conductive pad architecture configured as a universal solution for accommodating conductor wire placement variability and for protecting a printed circuit board 1100 from damage across multiple conductor joining processes.

A printed circuit board 1100 includes an electrically insulative base material 1102 and a conductive solder pad 1104 disposed at least partially over the electrically insulative base material 1102. A solder mask 1106 is disposed over the conductive solder pad 1104 and defines an exposed solder contact area 1108. A conductor wire 1110, such as an armature conductor wire, is positioned for connection to the exposed solder contact area 1108.

The conductor wire 1110 is shown exhibiting a spring displacement angle β_{SD}, which represents angular displacement of the conductor wire from a nominal placement orientation due to spring force. As used herein, “spring force” refers to an elastic restoring force of the conductor wire 1110 that biases the conductor wire 1110 toward a prior or relaxed shape (e.g., a pre-formed curvature) as a result of residual stress and elastic deformation introduced during upstream manufacturing operations such as winding, forming, cutting, and handling. The spring displacement angle β_{SD} is dependent on conductor wire diameter and on stresses imparted during prior manufacturing steps. Larger diameter conductors inherently exhibit larger spring forces and therefore greater spring displacement angles, making such conductors more difficult to place accurately.

In the illustrated embodiment, the spring displacement angle β_{SD} may vary over a defined range that accounts for minimum expected spring displacement and maximum expected spring displacement for larger diameter conductors. In one embodiment, β_{SD} ranges from approximately 5 degrees to approximately 25 degrees.

The conductive solder pad 1104 includes an extended pad portion 1114 that extends beyond the exposed solder contact area 1108 and underneath the solder mask 1106. The length of this extension is denoted W_{EP}. The extended pad portion 1114 provides additional conductive surface area to accommodate positional variation of the conductor wire 1110 resulting from spring force while protecting the electrically insulative base material 1102 from thermal, mechanical, and vibrational damage.

FIG. 11 further defines geometric parameters used to calculate the required pad extension. A width of the conductive solder pad 1104 is denoted W_{SA}. A length of the conductor wire 1110 necessary for connection to the solder pad 1104 is denoted L_{P}. A characteristic diameter, height, and width of the solder contact area 1108 is denoted H_{C}. These parameters collectively define the geometric relationship between conductor placement variation and required pad extension.

Positional tolerance of the conductor wire depends on conductor wire diameter and may be expressed as a function of the spring displacement angle β_{SD} and the conductor length L_{P} along the solder pad 1104. With a defined range of spring displacement angles, the required pad extension W_{EP} may be calculated using a trigonometric relationship, wherein lateral displacement of the conductor wire along the pad surface is determined using a sine function of β_{SD}. The extended pad portion 1114 is sized such that the conductor wire 1110 remains supported on the conductive solder pad 1104 throughout the full range of expected spring displacement.

With continued reference to FIG. 11, the positional tolerance of the conductor wire 1110 along the conductive solder pad 1104 is a function of the spring displacement angle β_{SD} and the conductor length L_{P} disposed over the solder pad 1104. The lateral displacement component introduced by spring force may be calculated using a trigonometric sine relationship. In one embodiment, the required extension length W_{EP} of the conductive solder pad 1104 satisfies the relationship:

$${W}_{E P} = [ ( {L}_{P} - \frac{1}{2} {W}_{S A} ) + \frac{1}{2} {H}_{C} ] sin ( {β}_{S D} )$$

wherein:
W_{EP} is the length of extension of the conductive solder pad;
W_{SA} is a width of the conductive solder pad;
L_{P} is the length of the conductor necessary for connection to the solder pad;
H_{C} is the diameter (height and width), respectively, of the solder contact area of the conductive solder pad; and
β_{SD} is the spring displacement angle, accounting the amount of angular displacement from spring force of the conductor.

This relationship defines the minimum pad extension necessary to accommodate angular displacement of the conductor wire 1110 due to spring force while maintaining electrical contact and protecting the electrically insulative base material 1102.

The spring displacement angle β_{SD} is dependent on conductor wire diameter and stresses imparted during prior electric motor winding and conductor forming processes. Larger diameter conductors inherently exhibit larger spring forces and therefore larger spring displacement angles, making such conductors more difficult to place. A defined range of spring displacement angles is therefore used to account for both minimum expected displacement and maximum expected displacement associated with larger diameter conductors, wherein β_{SD} may range from approximately 5 degrees to approximately 25 degrees.

As described above, spring force inherent in non-rigid conductors, such as armature conductor wires, introduces positional variation that is present prior to and independent of the joining process used. Regardless of whether a joining process is thermal, mechanical, electrical, or vibrational in nature, the conductor wire may elastically bias away from an intended placement orientation due to residual stress from upstream manufacturing operations. This spring-force-induced placement variability therefore interacts with each joining process in a different manner, influencing how thermal energy, mechanical force, current density, or vibrational energy is transferred at the conductor-to-pad interface and increasing the risk of localized stress and damage to the printed circuit board base material if not accommodated.

The embodiment of FIG. 11 is applicable across multiple joining processes, each of which presents distinct thermal and mechanical requirements that influence optimal pad geometry. In manual soldering applications, the extended pad portion 1114 provides dual protection mechanisms. First, it provides a thermal buffer zone that accommodates soldering iron placement tolerance, reducing the risk of damaging the electrically insulative base material 1102. Second, it provides positional accommodation for conductor wire placement variation caused by spring force. In such embodiments, pad mass is optimized to achieve sufficient base layer protection while maintaining acceptable thermal response characteristics. Excessive pad mass is avoided, as too much thermal mass slows the heating process and can compromise solder joint integrity.

In robotic soldering applications, variability in soldering tool placement is largely eliminated. However, robotic soldering cannot address the fundamental materials physics associated with conductor wire spring force. The extended pad portion 1114 compensates for this inherent limitation by providing adequate surface area to accommodate conductor wire placement variation while maintaining precise thermal control. In such embodiments, thermal profiles in the range of approximately 250° C. to 350° C. may be considered when optimizing pad geometry.

In mechanical joining processes, including thermal compression bonding and resistance welding, the joining operation introduces significant mechanical stress components in addition to thermal energy. In these embodiments, the extended pad portion 1114 provides structural reinforcement beyond thermal protection by distributing pressure-induced forces across a larger area of the conductive solder pad 1104, thereby preventing localized damage to the electrically insulative base material 1102.

For resistance welding applications, electrical performance considerations further influence pad geometry. In particular, current density requirements on the order of 150 to 300 A/mm² necessitate careful optimization of the conductive solder pad 1104 and extended pad portion 1114 to maintain acceptable current distribution while simultaneously providing mechanical protection and conductor placement tolerance.

In ultrasonic welding applications, the joining process introduces vibrational stress patterns that differ from purely thermal or pressure-based processes. In such embodiments, the extended pad portion 1114 functions as a mechanical dampener, distributing ultrasonic energy over a larger conductive area to prevent concentrated vibrational damage to the electrically insulative base material 1102. The pad extension thereby creates a stress distribution buffer that simultaneously accommodates both mechanical forces and conductor wire spring force variation.

Across all joining processes, a fundamental trade-off exists between protection capability and process performance, requiring process-specific geometric optimization of the extended pad portion 1114. Each joining method presents distinct thermal, mechanical, and electrical boundary conditions that influence optimal pad extension dimensions. The unifying technical principle across all embodiments is accommodation of conductor wire spring force, which is a materials-physics phenomenon affecting conductor placement regardless of automation level or energy source.

Accordingly, FIG. 11 illustrates an extended pad area architecture that transforms a solder pad from a process-specific feature into a generalized joining technology platform. By defining extended pad geometric relationships and conductor wire placement tolerance specifications applicable across multiple joining processes, the embodiment enables broad applicability with measurable performance parameters, while maintaining protection of the printed circuit board and reliable electrical connection formation.

It will be appreciated by those of ordinary skill in the pertinent art that the functions of several elements can, in alternative embodiments, be carried out by fewer elements, or a single element. Similarly, in some embodiments, any functional element can perform fewer, or different, operations than those described with respect to the illustrated embodiment. Also, functional elements shown as distinct for purposes of illustration can be incorporated within other functional elements in a particular embodiment.

While the subject technology has been described with respect to various embodiments, those skilled in the art will readily appreciate that various changes and/or modifications can be made to the subject technology without departing from the scope of the present disclosure.

What is claimed is:

1. A printed circuit board comprising:
an electrically insulative layer;
a conductive pad disposed at least partially over the electrically insulative layer, the conductive pad defining a contact area configured for making an electrical connection to a conductor; and
a solder mask coating the conductive pad and defining an exposed area of the conductive pad,
wherein the conductive pad protects the electrically insulative layer and accommodates positional variation of the conductor during attachment by extending a length underneath the solder mask along a periphery of the exposed area.

2. The printed circuit board of claim 1, wherein the length of extension of the conductive pad is dependent on a height and width of the contact area.

3. The printed circuit board of claim 1, wherein the length of extension of the conductive pad is dependent on a spring displacement angle of the conductor resulting from spring force inherent in the conductor.

4. The printed circuit board of claim 3, wherein the spring displacement angle accounts for placement variation introduced by conductor diameter and prior conductor manufacturing processes.

5. The printed circuit board of claim 4, wherein the spring displacement angle ranges between approximately 5 degrees and approximately 25 degrees.

6. The printed circuit board of claim 1, wherein the length of extension of the conductive pad is determined by the following equation:
$${W}_{E P} = [ ( {L}_{P} - \frac{1}{2} {W}_{S A} ) + \frac{1}{2} {H}_{C} ] sin ( {β}_{S D} )$$
wherein:
W_{EP} is the length of extension of the conductive pad;
L_{P} is a length of the conductor necessary for connection to the conductive pad;
W_{SA} is a width of the conductive pad;
H_{C} is a diameter (height and width) of the contact area of the conductive pad; and
β_{SD} is the spring displacement angle of the conductor.

7. The printed circuit board of claim 6, wherein β_{SD} is between approximately 5 degrees and approximately 25 degrees.

8. The printed circuit board of claim 1, wherein the conductive pad is fully disposed around the periphery of the contact area, less a channel for receiving the conductor.

9. The printed circuit board of claim 1, wherein the length of extension of the conductive pad is between approximately 0.25 millimeters and approximately 2.5 millimeters.

10. A printed circuit board comprising:
an insulative layer;
a conductive pad disposed over the insulative layer, the conductive pad defining a contact area for attachment of a conductor; and
a solder mask layer disposed over the conductive pad,
wherein the conductive pad extends underneath the solder mask layer to protect the insulative layer and to accommodate positional variation of the conductor during attachment.

11. The printed circuit board of claim 10, wherein a length of extension of the conductive pad is dependent on a height and width of the contact area.

12. The printed circuit board of claim 10, wherein the length of extension of the conductive pad is further dependent on a spring displacement angle of the conductor.

13. The printed circuit board of claim 12, wherein the spring displacement angle accounts for residual stress introduced during conductor winding, forming, and handling processes.

14. The printed circuit board of claim 13, wherein the spring displacement angle ranges between approximately 5 degrees and approximately 25 degrees.

15. The printed circuit board of claim 10, wherein the length of extension of the conductive pad is determined by the following equation:
$${W}_{E P} = [ ( {L}_{P} - \frac{1}{2} {W}_{S A} ) + \frac{1}{2} {H}_{C} ] sin ( {β}_{S D} )$$
wherein:
W_{EP} is the length of extension of the conductive pad;
L_{P} is a length of the conductor necessary for connection to the conductive pad;
W_{SA} is a width of the conductive pad;
H_{C} is a diameter (height and width) of the contact area of the conductive pad; and
β_{SD} is the spring displacement angle of the conductor.

16. The printed circuit board of claim 15, wherein β_{SD} is between approximately 5 degrees and approximately 25 degrees.

17. The printed circuit board of claim 10, wherein the conductive pad extends underneath the solder mask layer by between approximately 0.25 millimeters and approximately 2.5 millimeters.

18. The printed circuit board of claim 10, wherein the conductive pad extends underneath the solder mask layer along a periphery of the contact area.

19. The printed circuit board of claim 10, wherein the conductive pad extends underneath the solder mask layer along the periphery of the contact area, less a channel for receiving the conductor.

20. A method of creating a connection on a printed circuit board, the printed circuit board including an electrically insulating base layer, the method comprising:
placing a conductive pad adjacent the electrically insulating base layer, the conductive pad defining a contact area;
coating the conductive pad with a solder mask such that the conductive pad extends beyond the contact area and underneath the solder mask to form a peripheral extension, the contact area remaining exposed; and
attaching a conductor to the contact area using a joining process,
wherein the peripheral extension accommodates positional variation of the conductor caused by spring force and protects the electrically insulating base layer from damage incurred during the joining process.
